(19) United States
(12) Patent Application Publication
(10) Pub. No.: US 2021/0388486 A1
(43) Pub. Date: Dec. 16, 2021

(54) EVAPORATOR BOAT CONTROL SYSTEM, PVD MACHINE AND METHOD OF OPERATING THE PVD MACHINE

(71) Applicant: BOBST MANCHESTER LIMITED, Heywood (GB)

(72) Inventors: Omar NUNZIATI, Heywood (GB); Mark WALKER, Clitheroe Lancs (GB)

(73) Assignee: BOBST MANCHESTER LIMITED, Heywood (GB)

(21) Appl. No.: 17/287,452

(22) PCT Filed: Nov. 5, 2019
(86) PCT No.: PCT/EP2019/025380

§ 371 Date: Apr. 21, 2021

(30) Foreign Application Priority Data
Nov. 20, 2018 (EP) 18020614.6

(51) Int. Cl. C23C 14/54; C23C 14/26; C23C 14/24

(52) U.S. Cl. CPC C23C 14/543; C23C 14/246; C23C 14/26

(57) ABSTRACT

The invention relates to a system for controlling evaporator boats, having a fixture (16) for receiving a plurality of evaporator boats (14), an energy source (18) for providing energy for heating each of the evaporator boats (14), a supply wire drive (24) for each of the evaporator boats (14), at least one camera (32) adapted for capturing an image of at least one of a plurality of evaporator boats (14) mounted in the fixture (16), and a control (26), the control (26) having an image analyzation module (36) and being adapted for providing a control signal for the supply wire drive (24) and a control signal for the energy source (18), the control signals depending at least in part from an output of the image analyzation module (36). The invention further relates to a PVD machine and to a method of operating the machine.

The invention relates to an evaporator boat control system, to a PVD (physical vapour deposition) machine and to a method of operating the PVD machine.

A PVD machine is a machine with which a material is deposited on a substrate. The material forms a layer consisting of a metal and/or a metal oxide, such as aluminium oxide, on the substrate. The substrate can be a thin film (such as a plastic foil, paper or card) which may be used as a packaging material. Such a packaging material may be used for packaging food. The layer may be used to provide a barrier against ingress of gas and/or water and/or light. The layer provided on the foil, paper or card may be transparent and/or mechanically dense and/or mechanically stable.

In some types of PVD machines, evaporator boats are used for melting and evaporating the deposition material. The evaporator boats are resistively heated and are arranged in a process chamber so that a vacuum can be established for conducting the deposition process.

In the prior art, the resistively heated evaporator boats are controlled manually by the operator. The manual process involves the operator looking through a transparent window to visually inspect the aluminum pool on the evaporator boat and adjusting electrically via power, voltage or current to ensure an optimized pool shape of evaporant material based on variables such as wire feed rate, evaporant material, different processes (AlOₓ, Dark Night and AluBond) and evaporator boat age. Failure to do so will result in poor product quality and a reduction in life of the evaporator boats.

In a typical metallizing process the operator requires to make adjustments every 5 minutes to up to 60 evaporators for a 1 hr cycle time to ensure good product quality. This operator dependent task requires a very experienced machine operator as contrast between pool and boat surface is difficult and is the limiting factor to ensure product quality, maximizing yield and increasing the life of the evaporator boat.

The object of the invention is to make control of the evaporator boats easier.

This object is solved by a system for controlling evaporator boats, having a fixture for receiving a plurality of evaporator boats, an energy source for providing energy for heating each of the evaporator boats, a supply wire drive for each of the evaporator boats, at least one camera adapted for capturing an image of at least one of a plurality of evaporator boats mounted in the fixture, and a control, the control having an image analyzation module and being adapted for providing a control signal for the supply wire drive and a control signal for the energy source, the control signals depending at least in part from an output of the image analyzation module.

The above mentioned object is also solved with a physical vapor deposition machine having a web supply, a system for controlling evaporator boats as defined above, a process chamber in which at least the fixture for the evaporator boats, the supply wire drives and an area for depositing a web supply are arranged. The area for depositing a web supply can be formed by guiding the web around a process drum or by guiding the web between two guiding rollers.

Further, the above mentioned object is also solved with a method of operating the machine as previously defined, wherein the control signal for the energy source controls at least one of the power, the current and the voltage supplied to a respective evaporator boat.

Generally speaking, the gist of the invention is to use a camera system to identify at least one relevant parameter of the evaporant material on the evaporator boat, in particular the pool shape, and a suitable recognition software to provide closed loop electrical control of the evaporators to maintain the optimum pool shape. This results in an operator independent metallizing process with a maximum of quality, product yield and consumable utilization.

The control also provides a signal for controlling the speed with which the substrate to be deposited is advanced.

The energy source can provide a heating current for restrictive or inductive heating of the evaporator boats, which can be controlled very easily so as to maintain a desired temperature level for melting and evaporating the deposition material.

The supply wire drive preferably includes a stepper motor which allows controlling the desired amount of supply wire to the evaporator boat in a very precise manner.

A typical PVD machine has a plurality of evaporator boats. In order to reduce the costs for controlling the evaporator boats, one camera can capture the image of a plurality of evaporator boats, for example of four to six evaporator boats. It is a simple task to separate in the captured image the individual evaporator boats and to have the image analyzation module evaluate the individual images separately.

In order to facilitate image analyzation, a light filter or a light source may be provided for the camera to increase the contrast between the light emission of the boats and the light emission of the evaporant pool.

The camera is preferably arranged outside the process chamber so as to avoid contamination and in order to facilitate accessibility and maintenance but will be mounted within the process chamber if necessary.

The control uses a closed control loop which results in an optimal control of the evaporator boats and in a maximum output of the PVD process as regards yield and quality.

According to a preferred embodiment, a surface inspection system is provided for inspecting the surface of the web downstream of a deposition area, the control receiving an output signal of the surface inspection system. Taking into account not also parameters of the pool of molten materials on the evaporator boats but also a signal indicative of the quality of surface of the substrate onto which the deposition material has been deposited, further increases the quality of the control.

The amount of material supplied to the evaporator boats can be very easily and precisely controlled if the control signal for the supply wire drive controls the speed with which the supply wire is advanced towards the respective evaporator boat.

According to a preferred embodiment, a screen is provided for visualizing at least one parameter relevant for the control of the evaporator boats, the parameter being at least one of the shape of the pool of molten material and possibly also of the temperature of the molten material. The parameter can be visualized in a manner which allows an operator to more quickly grasp the relevant information. As an example, the contour of the pool of molten material is depicted in a specific color, or the surface of the pool of molten material is made more visible against the surface of the evaporator boat.

For an optimum control of the evaporator boats, the image analyzation module analyzes at least one of the following parameters: shape of a pool of molten material or ceramic evaporator, size of pool of molten material, temperature of the molten material and/or ceramic boats, and aspect ratio of the pool of molten material. Information on the shape and size of the pool of molten material allows determining in particular the amount of deposition material which should be supplied to the evaporator boats. Information on the temperature of the pool and/or the evaporator boat is relevant for controlling the amount of energy supplied to the evaporator boats for heating. Information on the aspect ratio allows assessing the age of the evaporator boats. This information is relevant as a new evaporator boat should be heated in a different manner than an already used evaporator boat.

In an alternative embodiment, the information on the age of the respective evaporator boat is provided to the control in a different manner, e.g. by directly indicating when evaporator boats have been replaced, so as to allow the control to take age information into account.

According to a preferred embodiment, the control uses different sets of target parameters for the evaporator boats for different evaporator materials. The different target parameters can be retrieved from a database so that different information on e.g. the optimum pool shape is being used for different deposition materials and for different types of deposition processes.

The invention will now be described with reference to an embodiment which is shown in the enclosed drawings. In the drawings:

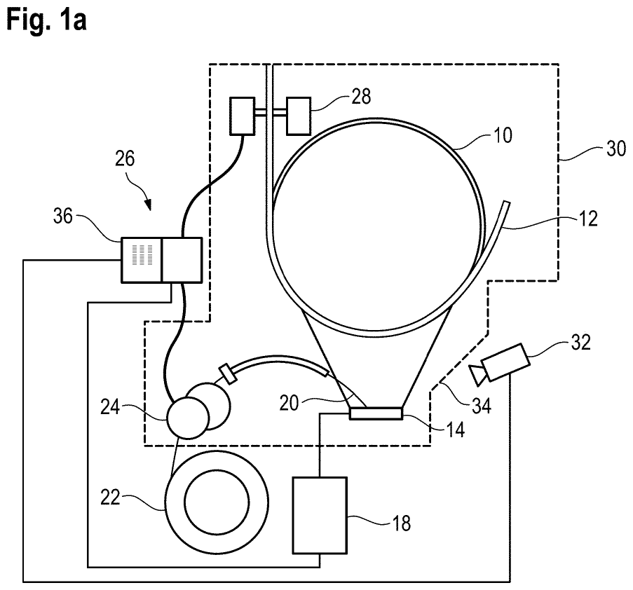

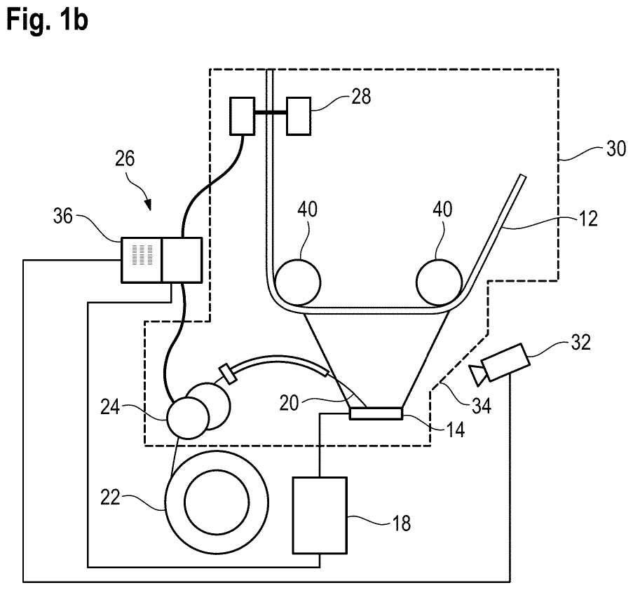

FIGS. 1a and 1b are schematic views of a PVD machine according to the invention;

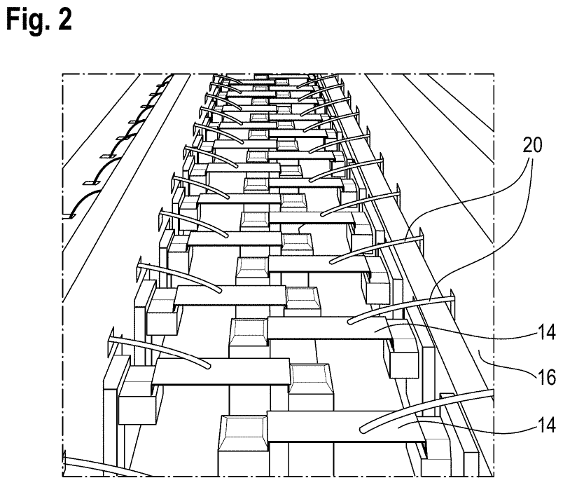

FIG. 2 is a schematic view of a fixture for evaporator boats as used in the machine of FIGS. 1a and 1b;

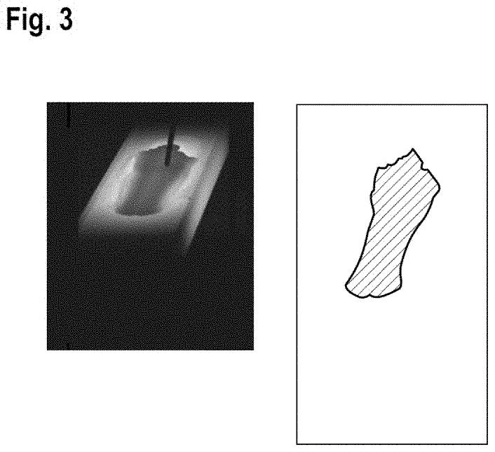

FIG. 3 is a schematic view of a visualization of a pool of molten material on an evaporator boat;

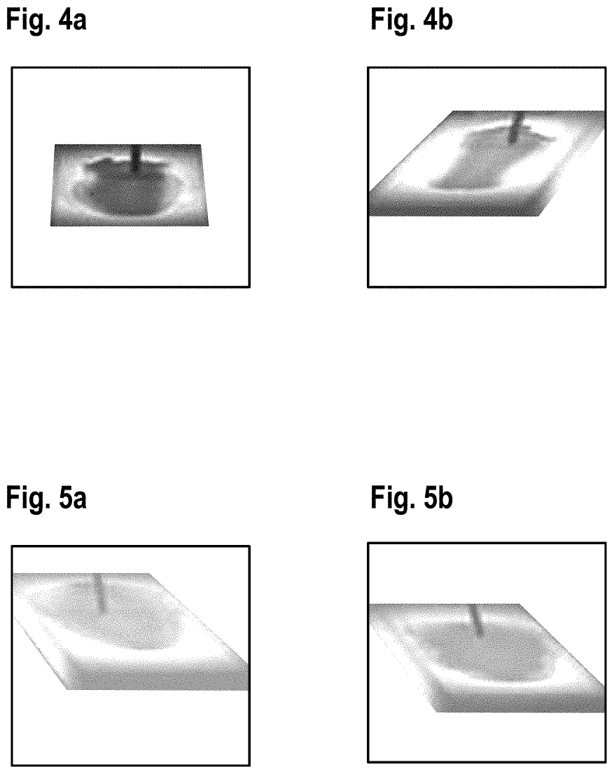

FIGS. 4a and 4b are examples of images captured from an evaporator boat via the camera of the PVD machine, with the pool of molten material having the desired shape;

FIGS. 5a and 5b are examples of images captured from an evaporator boat via the camera of the PVD machine, with the pool of molten material being too large;

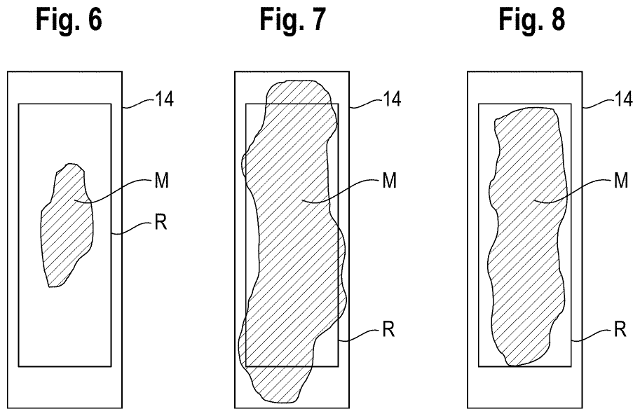

FIG. 6 is a schematic representation of the pool of molten material on an evaporator boat, with the pool being too small;

FIG. 7 is a schematic representation of the pool of molten material on an evaporator boat, with the pool being too large;

FIG. 8 is a schematic representation of the pool of molten material on an evaporator boat, with the pool having the desired size;

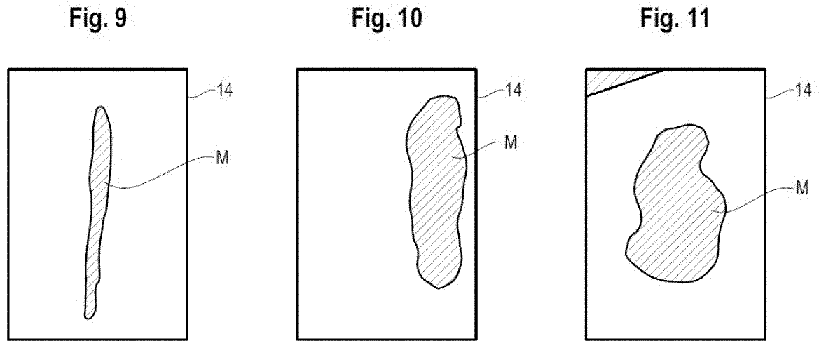

FIG. 9 is a schematic representation of a pool of molten material on a new evaporator boat;

FIG. 10 is a schematic representation of a pool of molten material caused by a de-centered wire supply;

FIG. 11 is a schematic representation of an evaporator boat having a contact issue; and

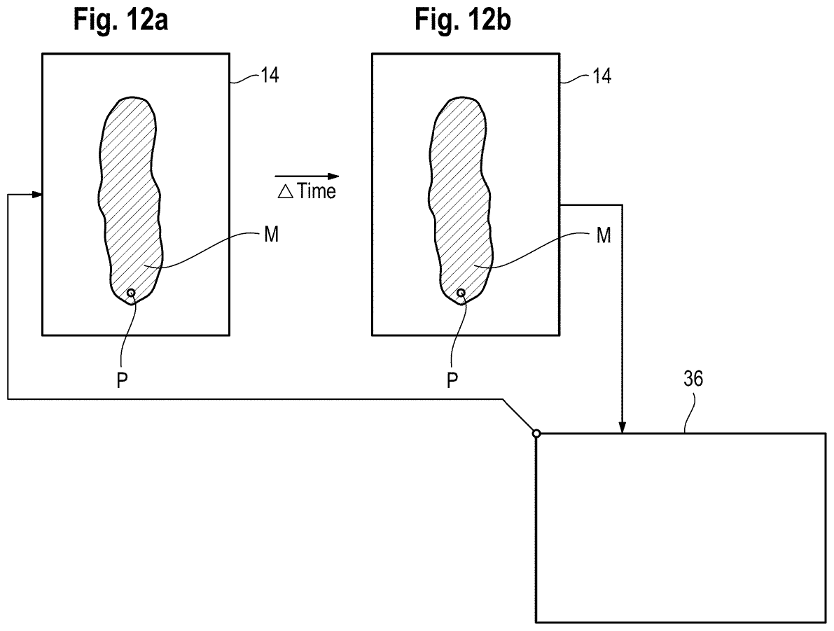

FIGS. 12a and 12b are a schematic representation of an analyzation of the pool of molten material regarding defects.

In FIGS. 1a and 1b, the essential components of a PVD machine are shown. It comprises a process drum 10 or free span rollers 40 around which a substrate 12 in the form of a web is guided. Substrate 12 can be a thin plastic foil which is used for packaging food.

Details of the way in which substrate 12 is provided and guided (such as a supply reel, guiding rollers, a take-up reel, etc.) are not shown here as they are not relevant for understanding the invention.

For providing a deposition material to be deposited on substrate 12, a plurality of evaporator boats 14 is provided in the vicinity of process drum 10. Evaporator boats 14 are arranged in a fixture 16 so as to form a row of adjacent evaporator boats, the row being arranged in parallel with the axis of rotation of process drum 10 so that the entirety of the evaporator boats 14 extends over the entire width of substrate 12.

In the FIG. 2 configuration, evaporator boats are shown in a staggered arrangement relative to one another. Other arrangements are possible, e.g. arranging the evaporator boats in line.

Fixture 16 is adapted for supplying electric energy from an energy source 18 (schematically depicted in FIGS. 1a and 1b) to evaporator boats 14. The amount of energy supplied to evaporator boats 14 can be controlled separately for each evaporator boat 14.

Depending on the width of substrate 12, up to 60 evaporator boats 14 can be arranged adjacent each other in fixture 16.

The deposition material is supplied to each of the evaporator boats 14 in the form of a supply wire 20 which is stored on a supply reel 22. For each of the evaporator boats 14, a supply wire drive 24 is provided which control the speed with which supply wire 20 is advanced towards the respective evaporator boat 14.

Drive 24 is here implemented in the form of a stepper motor.

A control 26 is provided for controlling various functions of the PVD machine.

Control 26 controls the amount of energy provided to each of the evaporator boats 14. Further, control 26 controls the speed of drive 24.

Also connected to control 26 is a surface inspection system 28 which inspects the surface of substrate 12 downstream of process drum 10. Surface defects of the substrate provided with the deposition material as well as other quality issues can be detected by surface inspection system.

A process chamber 30 is formed which allows establishing a vacuum in the area in which the deposition material is deposited on substrate 12.

At least one camera 32 is provided for capturing an image of at least one of the evaporator boats 14. The term “camera” here designates each and every device which is able convert optical information within the viewing area of the device into electronic information.

It is possible to use one camera 32 for each of the evaporator boats 14. In order to reduce the number of necessary cameras 32, it however is preferred to use cameras 32 which each cover a plurality of evaporator boats 14. As an example, each of the cameras 32 can capture the images of six evaporator boats 14.

Cameras 32 are arranged outside of process chamber 30. A viewing window 34 is provided in a wall of process chamber 30 so as to allow the cameras to capture the images of the evaporator boats 14.

The images captured by cameras 32 (infrared and light emission) are supplied to control 26, in particular to an image analyzation module 36 which is part of control 26.

In order to facilitate image analyzation, a light filter (not shown) or a light source may be provided for the camera to increase the contrast between the surface of the pool of molten material and the surface of the evaporator boat 14. The filter facilitates detection of the pool of molten material on the evaporator boats 14.

Image analyzation module 36 is adapted for analysing the information provided by cameras 32, in particular as regards the shape of a pool of molten deposition material on each of the evaporator boats 14. The shape of the pool of molten deposition material on the evaporator boats 14 is the most relevant parameter for controlling the evaporator boats 14, in particular as regards the amount of deposition material supplied in the form of supply wire 20, and as regards the temperature of the evaporator boats 14 established by means of the amount of energy supplied from energy source 18.

Part of image analyzation module 36 is a database in which information on target pool shapes is stored. The target pool shapes can be considered as the optimum shape of the pool of molten material for the specific deposition characteristics required and also for different ages of evaporator boats 14 as the optimum shape of the pool changes when a new evaporator boat 14 is compared with an old, almost consumed evaporator boat 14.

Information on the age of the evaporator boats 14 can be obtained by the determination of the aspect ratio for the individual evaporator boats 14.

During operation of the PVD machine, image analyzation module 36 analyses the shape of the pool of molten material on each of the evaporator boats 14 (for example by means of a suitable recognition software) and compares it with a target shape. Depending from the difference between the actual shape and the target shape, control 26 controls stepper motor 24 to appropriately supply deposition material to the respective evaporator boat 14, and controls energy source 18 to appropriately set the temperature of the evaporator boat 14. Controlling energy source 18 can involve changing the power, the voltage and/or the current supplied to the evaporator boats 14.

New evaporator boats 14 can be determined via aspect ratio detection.

The overall aim of control 26 is to achieve the optimum pool shape and optimum boat coverage.

Additionally, control 26 can visualize the determined shape of the pool of molten material on a screen for inspection by an operator. Visualization can in particular not only involve displaying the actual image captured by cameras 32 (see the image on the left in FIG. 3), but also involve depiction of a contrast-optimized image (see the image on the right side in FIG. 3).

For an optimum control, a close loop defect control is established which also takes into account information provided by surface inspection system 28.

Examples of images captured with one of the cameras 32 are shown in FIGS. 4a to 5b.

In FIGS. 4a and 4b, the pool shape and size are as desired. Supply voltage and power are balanced for the wire feed rate and the boat age.

In FIGS. 5a and 5b, the size of the pool is too large. The evaporator boat is too cold so that the supply power/voltage should be increased to increase the temperature, or the wire feed rate should be decreased.

In FIGS. 6 to 8, schematic examples of different pools of molten material on an evaporator boat are shown. With reference numeral R, a virtual reference frame is symbolized which can be used by the image analyzation module 36 for determining the size of the pool. Depending from the analysis of the captured image, the control controls the heating power supplied to the evaporator boats.

In FIG. 6, the pool of molten material M is too small. This is because the temperature of the evaporator boat is too high so that the evaporation rate is too high. The control is to decrease the heating power supplied to the evaporator boat.

In FIG. 7, the pool of molten material M is too large. This is because the temperature of the evaporator boat is too low so that the evaporation rate is too low. The control is to increase the heating power supplied to the evaporator boat.

In FIG. 8, the pool of molten material M has a desired size. This is because there is an equilibrium between boat temperature, supplied heating power and metal wire feeding.

After starting a deposition process, the control monitors any change of the shape of the pool of molten material M. Should the size of the pool increase from the desired condition (like in FIG. 8) increase (towards the size shown in FIG. 7), the evaporation rate is lower than it should be. Accordingly, the control will either decrease the wire feed rate or increase the power supplied to the evaporator boat, in order to prevent defects on the final product and damage to the web barrier.

The comparison between the different shapes of the pool at the start of the deposition process can take into account the evolvement over a time period.

FIG. 8 is a schematic representation of a pool of molten material during standard production. Depending upon the evaporator boat used and other factors, the pool covers different areas of the surface of the evaporator boat.

Suitable pool shapes are stored in a database so that they are available for the machine control.

If different types of processes are to be carried out, the image analyzation module 36 can control the pool so as to assume a different shape/size.

The image analyzation module 36 allows identifying potential issues and also other parameters, as will be explained with reference to FIGS. 9 to 11.

In FIG. 9, a pool of molten material can be seen which is characteristic for a new evaporator boat. It can be determined on the basis of the aspect ratio of the pool of molten material. The length of the pool is more than 5 times the width.

In FIG. 10, the entire pool is offset. This is the result of the supply wire being out of center. The control can determine this issue and indicate a warning or some other note on a control display, making an operator understand that there is a problem which should be fixed.

In FIG. 11, the light emission of the evaporator boat 14 is schematically shown, with the upper left corner emitting significantly more light than the rest of the evaporator boat 14. This indicates a problem with the electric contact from the fixture 16 to the evaporator boat, in particular a high electric resistance so that heat is generated at the point of contact.

The excessive heat can be shown on a display with an augmented reality visualization so that an operator very quickly understands the nature of the problem.

In FIGS. 12a and 12b, another example of evaluation of potential issues on the evaporator boat 14 is shown. Here, pin holes P or other defects of the pool of molten material M are monitored and possible changes over the time period are evaluated. This allows a detection of pool state and pool time trend and can influence the control of an ongoing deposition process.

1. A system for controlling evaporator boats, the system comprising:
a fixture for receiving a plurality of evaporator boats;
an energy source for providing energy for heating each of the plurality of evaporator boats;
a supply wire drive for each of the plurality of evaporator boats;
at least one camera adapted for capturing an image of at least one of the plurality of evaporator boats mounted in the fixture; and
a controller having an image analyzation module, the controller being configured to:
provide a first control signal for the supply wire drive; and
provide a second control signal for the energy source, the first control signal and the second control signal depending at least in part from an output of the image analyzation module.

2. The system of claim 1, wherein the at least one camera captures the image of a plurality of the plurality of evaporator boats.

3. The system of claim 1, further comprising: a light filter.

4. The system of claim 1, wherein the controller is further configured to provide a third control signal for a transport speed of a substrate to be deposited.

5. A PVD machine comprising:
a web supply,
a system for controlling evaporator boats as claimed in claim 1, and
a process chamber in which at least the fixture for the evaporator boats (14), the supply wire drive, and an area for depositing the web supply are arranged.

6. The machine of claim 5, wherein the at least one camera is arranged outside and/or inside the process chamber.

7. The machine of claim 5, wherein the controller uses a closed control loop.

8. The machine of claim 5, further comprising a surface inspection system for inspecting a surface of a web downstream of a deposition area, and
the controller is further configured to receive an output signal of the surface inspection system.

9. The machine of claim 5, further comprising a screen for displaying a visualization of at least one parameter relevant for the control of the evaporator boats, the at least one parameter being at least one of a shape of a pool of molten material and a temperature of the molten material.

10. The machine of claim 9, wherein the visualization has color enhancements to highlight process problems.

11. A method of operating a PVD machine as claimed in claim 5, wherein the second control signal for the energy source controls at least one of a power, a current and a voltage supplied to a respective evaporator boat and depends from the output of the image analyzation module.

12. The method of claim 11, wherein the controller is further configured to provide a third control signal for a transport speed of a substrate to be deposited, the third control signal depending at least in part from the output of the image analyzation module.

13. The method of claim 11, wherein the first control signal for the supply wire drive controls a speed with which a supply wire is advanced towards respective evaporator boats.

14. The method of claim 11, wherein the image analyzation module is configured to analyze at least one parameter of a set of parameters, the set of parameters including:
a shape of a pool of molten material or evaporator boat,
a size of the pool of molten material,
a temperature of the molten material and/or evaporator boat, and
an aspect ratio of the pool of molten material.

15. The method of claim 11, wherein the controller takes into account information on an age of a respective evaporator boat.

16. The method of claim 11, wherein the controller uses different sets of target parameters for the plurality of evaporator boats for different evaporator materials, different evaporator boat dimensions, and/or different deposition requirements.
